(19) United States
(12) Patent Application Publication
(10) Pub. No.: US 2007/0148558 A1
(43) Pub. Date: Jun. 28, 2007

(54) Double metal collimated photo masks, diffraction gratings, optics system, and method related thereto

(76) Inventor: Shahzad Akbar, Colonial Heights, VA (US)

Correspondence Address: Andrew J Befumo, 6237 Tidewater Trail, Church View, VA, 23032, US

(21) Appl. No.: 11/318,712

(22) Filed: Dec. 27, 2005

(51) Int. Cl. G03F 9/00; G03F 1/00

(52) U.S. Cl. 430/5; 430/22

(57) ABSTRACT

A photo mask having at least 2 mask pattern layers disposed to collimate light patterns passing through the mask. An improved optical photo lithographic system utilizing light collimating photo masks to improve resolution, depth of focus and field size. A method of manufacturing integrated circuit chips utilizing light collimating photo mask technology.

### FIELD OF THE INVENTION

This invention relates to diffraction gratings and optical photo masks in general, and to lithographic photo masks in particular. Specifically the invention is a light collimating optical diffraction grating, a light collimating lithographic photo mask, and a complete lithographic system, including the imaging camera and alignment system using the light collimating mask.

### BACKGROUND OF THE INVENTION

Photolithography involves the transfer of a pattern from a mask to a wafer with light, and is a well established, critical enabling technology used extensively for decades in the manufacturing of semiconductor integrated circuits, printed circuit boards and for other applications. This photolithographic process is typically completed in a stepper, which includes a light source and a mask, in addition to other components. A mask for use in the stepper is fabricated with a desired pattern that corresponds to features to be formed on the wafer. Low wavelength optical radiation, usually in the ultraviolet, extreme ultra-violet or x-ray regions, is used to illuminate the photo mask stencil, which typically comprises a chromium metal opaque enlarged pattern etched onto a transparent quartz substrate. Light passing through the mask is reduced through a complex system of optical lenses to expose a small field on a photosensitive resist thin film deposited on the wafer. Thus the exposed area on the photosensitive resist thin film is in accordance with the pattern of the mask. The latent image formed on the resist is then developed and transferred to the underlying substrate by etching or ion implantation or by other processes and the resist is stripped. The lithographic and etch processes are repeated many times during the fabrication of semiconductor devices such as DRAM memory or CMOS logic chips.

A basic photo mask comprises a single metal binary stencil mask. These masks are usually comprised of a chromium and chromium oxide thin film on a rectangular quartz substrate transparent to the actinic radiation. Binary masks are either clear field or dark field, depending upon whether or not the background is left clear or opaque.

The smallest feature size that a mask can print on the wafer is called the resolution of the lithographic system. Prior art masks, which typically consist of a single metal opaque layer, suffer from limited resolution due to optical diffraction at the edges of the opaque layer. The result of the optical diffraction is that the light intensity projected on to the photosensitive resist is non-uniform; thus a rectangle is printed as an oval on the wafer. Increasing the numerical aperture of the lens system to improve the resolution rapidly decreases the depth of focus. A reduction in depth of focus results in a loss of pattern information transferred to the wafer, and increases the need to planarize the surface topology of the wafer through additional process steps such as chemical mechanical polishing.

Several approaches have been developed to address the optical limitations associated with current photo mask systems. However, these techniques suffer from drawbacks that add expense to the development and manufacture of micro circuitry.

Software image manipulation techniques called Optical Proximity Correction (OPC) are often employed to somewhat mitigate the deleterious effects of limited resolution and depth of focus. OPC techniques add additional pattern features—at the corners of a rectangle, for example—to make the resulting oval image appear closer to the desired shape. U.S. Pat. No. 5,900,338 to Gaza discloses an OPC method for identifying regions of an integrated circuit layout design where optical proximity correction will be most useful, and then performing optical proximity correction on those regions only. However, techniques that use OPC on individual features on a wafer often have the unintended consequence of causing two or more features to intersect, rendering the wafer useless, while applying OPC techniques to correct a full mask design requires substantial time and computing power.

Off axis illumination has been used to attempt to improve the resolution of a photo lithographic system. These systems typically introduce diffraction gratings in the optical path of the off-axis light by, for example, inserting the diffraction grating into the system or etching a diffraction grating into the backside of the quartz substrate of a single metal photo mask. Because of technical problems such as decreased illumination intensity, image distortion, lower throughput and the expense of modifying the lithographic system, off axis illumination is seldom used in modem IC chip fabrication. The present invention does not suffer from the problems associated with off axis illumination as the light is incident vertically upon the mask and the two opaque image planes increase the depth of focus.

Phase shifting photo masks have also been used to improve image quality and resolution. Phase shifting photo masks contain regions of optical phase shifting materials such as molybdenum silicide, and can be either attenuated phase shift masks or alternating phase shift masks. The underlying concept of the phase shifting photo mask is to introduce canceling interference of impinging light at portions of an image where diffraction effects have deteriorated the resolution of the image. The use of a phase shift mask typically involves fabricating and testing several different masks, each with a unique transmission percentage, and experimentally determining the optimal percentage of light transmission for the particular application. This is a very costly and time consuming process.

The double metal collimated photo masks of the present invention radically changes the optics of the lithographic system by decreasing the undesirable diffraction effects at the edges of the opaque pattern by collimating the light beam when it passes through two or more opaque metal mask pattern layers. The light intensity is therefore spread uniformly through out the mask pattern and the image integrity and quality is enhanced, resulting in improved resolution. A rectangle therefore retains the shape of a rectangle because a greater amount of image information has been transferred to the photosensitive resist. The resulting optics of the total lithographic system is thereby improved with less aberration, stigmatism, coma and image distortion effects. The larger focus-exposure latitude decreases the need for OPC, Attenuated Phase Shifting and other resolution enhancement technologies. Additionally, the depth of focus is greatly increased because the image can stay in focus from any opaque layer within the system as the distance between the lens and the substrate is varied. The larger DOF widens the lithographic process latitude and reduces the need for surface topology planarity previously accomplished by CMP Chemical Mechanical Polishing. This invention would also enable an increase in the area of the stepping field repeated in a stepper lithographic camera, thereby increasing the wafer throughput. As the minimum critical dimension feature size decreases to the range of 100 nm or, the enhanced double metal masks would be cost effective, especially since they delay the need to introduce more expensive lithographic systems in semiconductor production fabrication facilities.

It is therefore an object of the present invention to provide a photo mask that collimates light.

Another object of the present invention is to provide a diffraction grating that collimates light.

Another object of the present invention is to provide a photo mask that reduces light diffraction.

Another object of the present invention is to provide a photo mask that increases depth of focus.

Another object of the present invention is to provide a light collimating optical photolithographic system.

Another object of the present invention is to provide a method of manufacturing IC chips at a reduced cost.

### SUMMARY OF THE INVENTION

The present invention is directed toward a mask adapted to collimate light. The mask has at least one substantially transparent substrate layer having a first side and a second side. Primary and secondary mask patterns comprise opaque layers formed on the substrate. The primary and secondary mask patterns are adapted to act in unison to collimate light passing through unmasked portions of the substrate.

An optical projection lithographic system according to the present invention comprises at least one light collimating lithographic photo mask and at least one light source. The light source is disposed to direct light energy to a first side of the lithographic photo mask. Light passing through the photo mask is collimated and projected at a target.

A method of manufacturing integrated circuit chips according to the present invention comprises the steps of: Providing a light collimating optical projection lithographic apparatus; Providing a wafer having a layer of photo-resist disposed thereon; Placing the wafer in the optical projection lithographic apparatus whereby collimated light exposes a pattern of the photo-resist layer, and transferring the pattern from the photo-resist layer to the underlying wafer.

### BRIEF DESCRIPTION OF THE DRAWINGS

The accompanying drawings illustrate a complete embodiment of the invention according to the best modes so far devised for the practical application of the principles thereof, and in which:

FIG. 1 depicts the double metal light collimating photo mask and diffraction grating of the present invention.

FIG. 2 depicts a stacked series of double metal light collimating photo masks and diffraction gratings of the present invention.

FIG. 3-A and FIG. 3-B depict a light collimating stack of single metal photo masks and diffraction gratings according to the present invention.

FIG. 4-A through 4-C depict light collimating photo masks and diffraction gratings of the present invention wherein one or more mask features on a mask layer have a dimensional offset with respect to the same features on other mask layers.

FIG. 5 Depicts a prior art single metal photo mask system.

FIG. 6 depicts an optical lithographic system of the present invention.

### DETAILED DESCRIPTION OF THE PREFERRED EMBODIMENTS

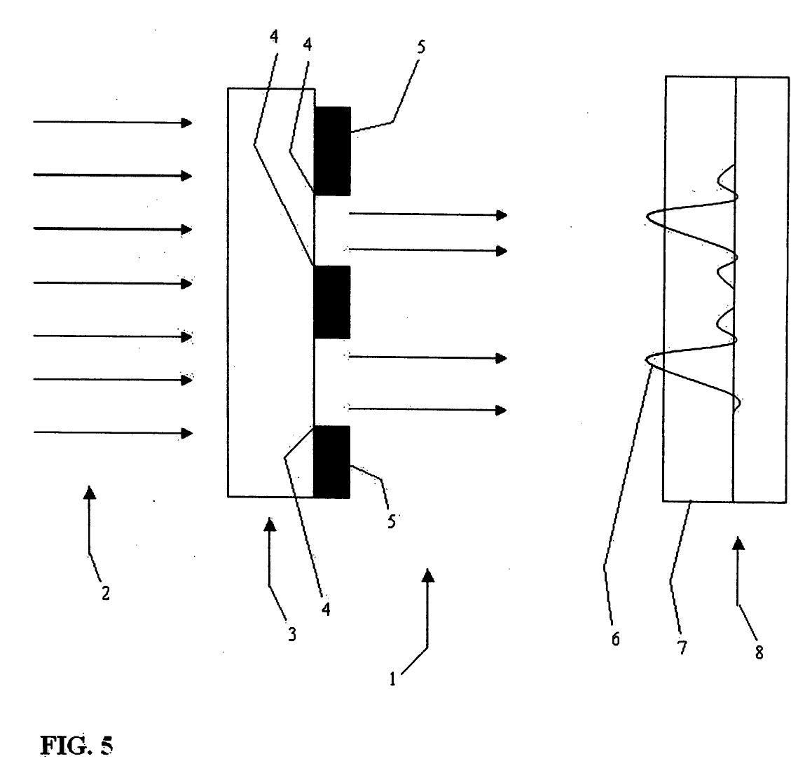

FIG. 5 depicts a prior art optical photo mask system 1, wherein light 2 is projected through a prior art photo mask 3, onto a photo resist layer 7 of a wafer 8. Diffraction effects which occur at edges 4 of opaque regions 5 of the photo mask 3 cause a loss of pattern information, and the resulting light intensity 6 projected on the photo resist layer 7 is non-uniform.

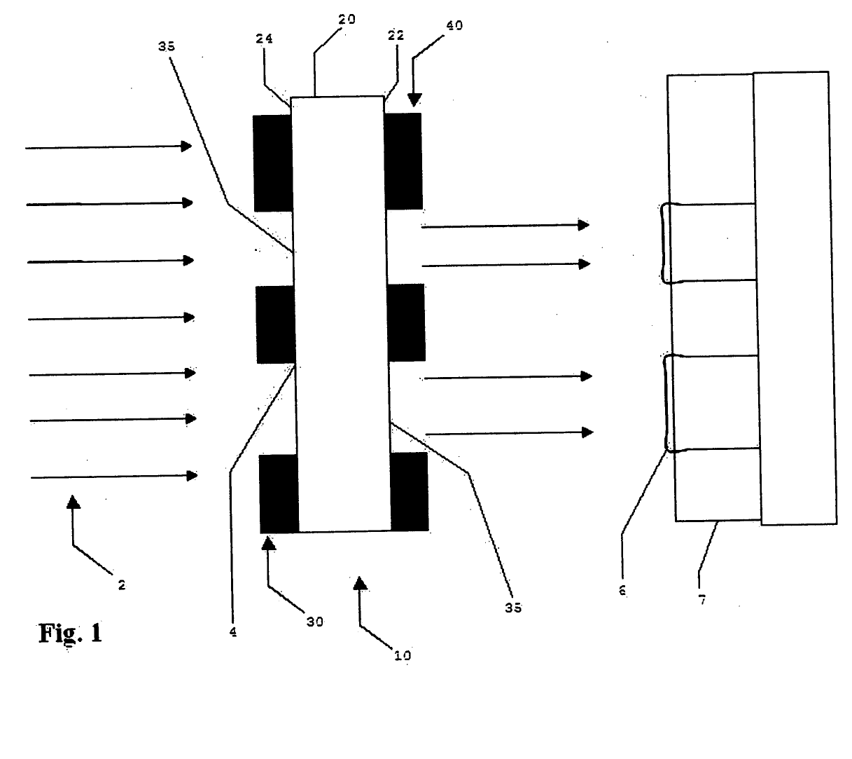

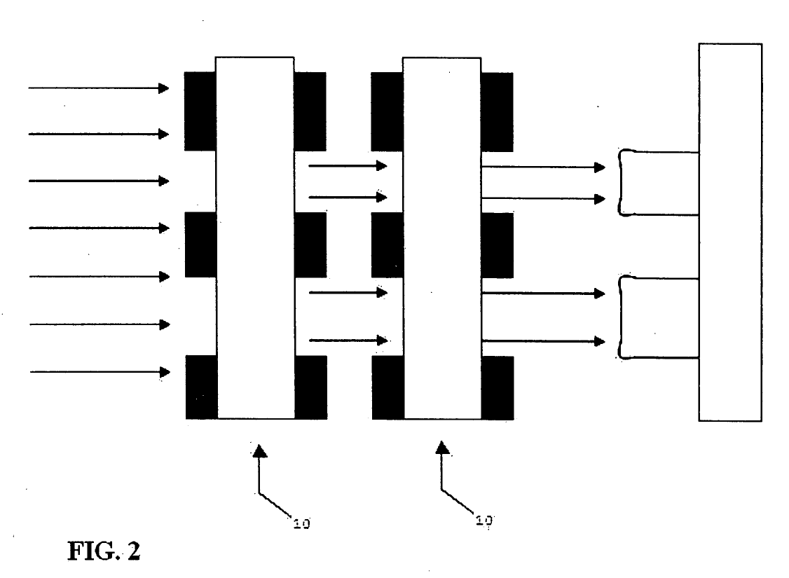

FIG. 1 depicts the photo mask 10 of the present invention. The photo mask 10 comprises at least one substantially transparent substrate 20 having two sides 22, 24 which are separated by the thickness of the substrate 20. The substrate 20 is any substrate known to those of average skill in the art, and is preferably selected from the group consisting of quartz, LE-30, White Crown, borosilicate glass, and Soda Lime glass. In a preferred embodiment of the present invention the substrate 20 is quartz. Other appropriate substrates are readily discoverable by those of skill in the art, and the scope of this disclosure is not meant to be limited by the mention of any particular substrate.

Still referring to FIG. 1, a primary mask pattern 30 and a secondary mask pattern 40 cover substantially identical regions of the substrate 20. The mask patterns 30, 40 act together to collimate light 2 passing through unmasked regions 35 of the substrate 20. The collimation of the light results in conservation of image information, and the resulting light intensity 6 projected on the photo resist layer 7 is uniform. It should be noted that throughout this application the word opaque is meant to include any material known to those of average skill in the art for masking regions of a photo mask substrate, and this definition may differ from the textbook definition of the work opaque. The opaque layer comprises either one, or a combination of elements selected from the group consisting of chromium, chromium oxide, chromium with chromium oxide, molybdenum, tungsten, titanium compounds, molybdenum silicon oxynitride, chrome oxynitride, and chromium aluminum oxynitride. However, the scope of this disclosure is not meant to be limited by the mention of any particular opaque material.

In an embodiment of the invention as shown in FIG. 1, the photo mask 10 comprises a double metal photo mask wherein the mask patterns 30, 40 reside on opposite sides 22, 24 of a single substrate 20. In this embodiment the two mask patterns 30, 40 are separated by the thickness of a single substrate 20, and are aligned with respect to each other, such that one mask pattern 30 covers substantially the same regions of the substrate as the other mask pattern 40. Light beams passing through the unmasked regions 35 of the substrate 20 become collimated, thus decreasing undesirable diffraction effects at the edges 4 of the mask pattern 30, 40. The resulting uniformity of light intensity improves image integrity, image quality and resolution, and can result in a larger image field size.

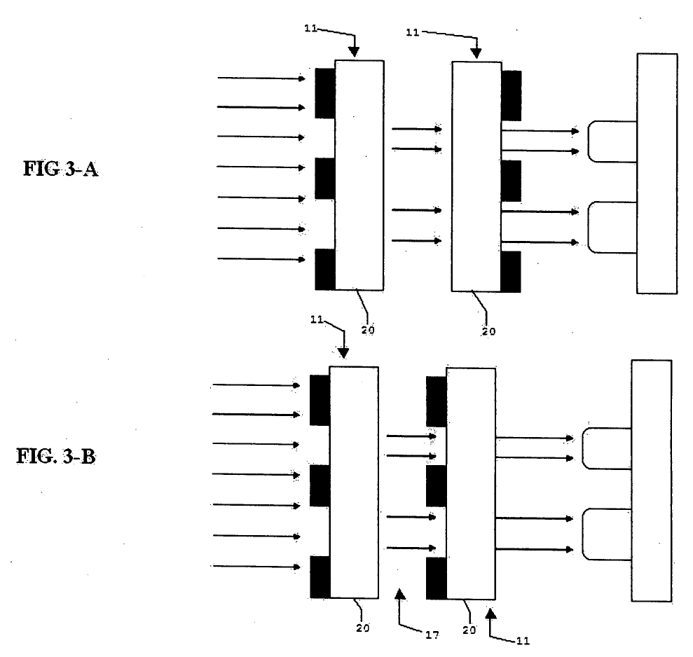

In an alternative embodiment of the present invention as shown in FIG. 2, a plurality of substantially identical double metal masks 10 are aligned in a stack. Adding additional mask layers improves light collimation. In an alternate embodiment of the present invention as shown in FIG. 3-A and FIG. 3-B, a plurality of single sided masks 11, adapted to mask substantially identical regions of a plurality of substrates 20 are aligned in a stack to achieve light collimation. Those of average skill in the art will recognize that multiple combinations of single sided and double metal masks can be stacked to achieve light collimation as presently disclosed. Referring back to FIG. 1, the thickness of the substrate in a double metal mask 10, and therefore the distance between the mask patterns 30, 40 can be varied to achieve the best image quality and depth of focus and field size. Additionally, when using multiple masks in a stack, the number of masks and the distance between the masks 17 (FIG. 3-B) can be varied to obtain the desired image quality and depth of focus. The best distance between mask layers in both stacked and single mask systems is readily determinable by one of average skill in the art without undue experimentation.

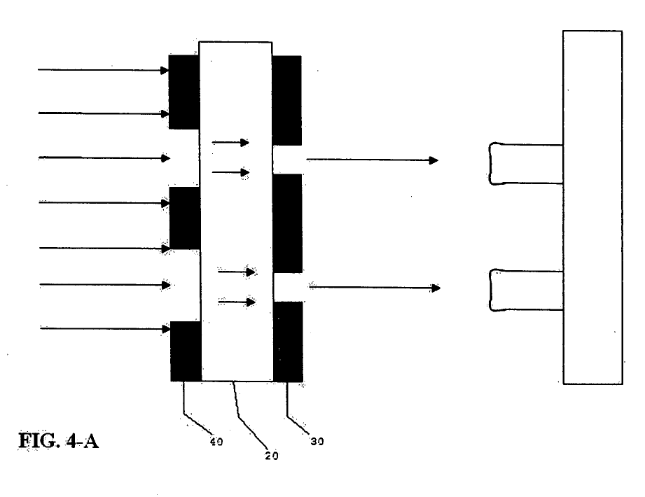

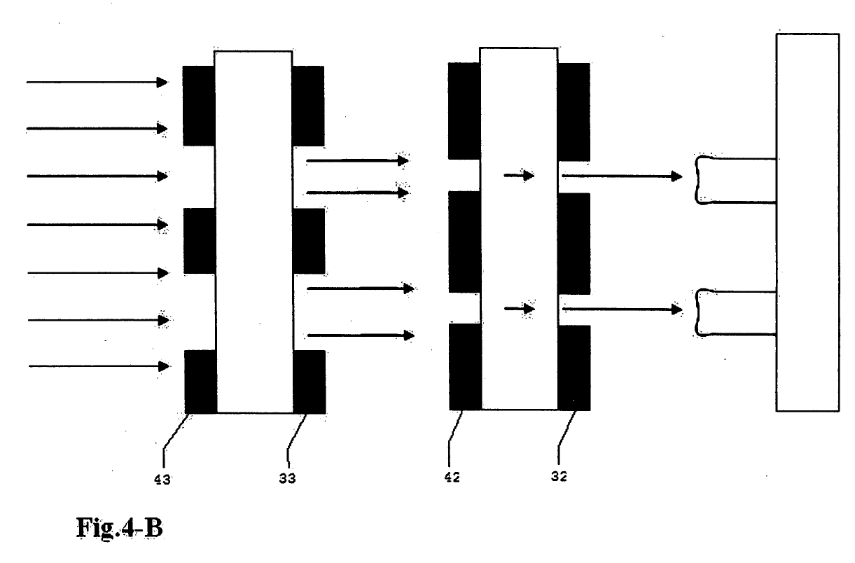

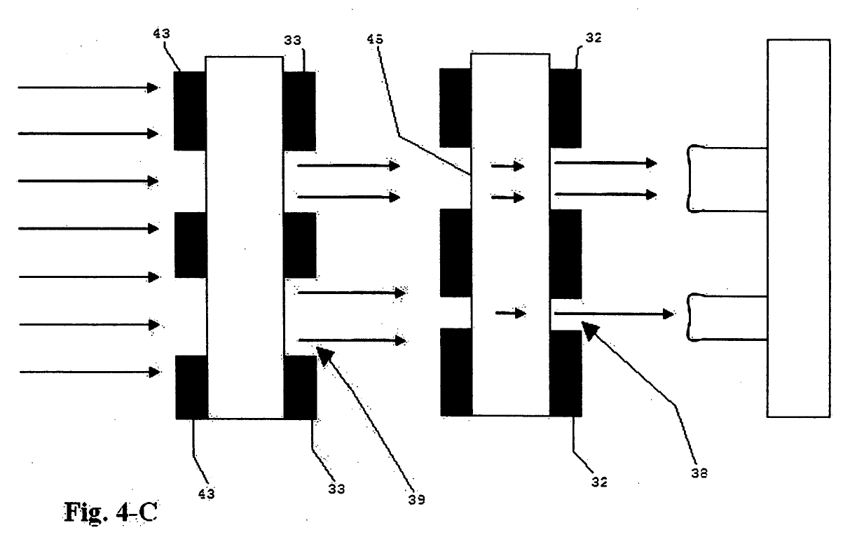

In yet another embodiment of the invention as shown in FIGS. 4-A through 4-C, one or more mask patterns have a dimensional offset with respect to other mask patterns in an optical system. FIG. 4-A shows a secondary mask pattern 40 having a dimensional offset with respect to a primary mask pattern 30. In this embodiment the secondary mask pattern 40 masks regions of substrate 20 not masked by the primary mask pattern 30, reducing the incident radiation. FIG. 4-B shows one or more mask patterns 32, 42 in a stack of masks having a dimensional offset with respect to other mask patterns 33, 43 in the stack. In FIG. 4-C, a particular feature 38 within a mask pattern 32 has a dimensional offset with respect to the same feature 39 in other masks patterns 33, 43 in the stack, while other features 45 have no offset. The effect of the dimensional offset is to further improve image resolution. When used in an optical lithographic system the light collimating mask with the dimensional offset allows smaller features to be exposed on the photo resist at higher resolutions than otherwise possible.

Photo masks according to the present invention can be lithographic photo masks, or diffraction gratings. Other uses for light collimating photo masks such as in the production of printed circuit boards, flat panel displays, and television screens will be apparent to those of average skill in the art and are considered within the scope of this invention.

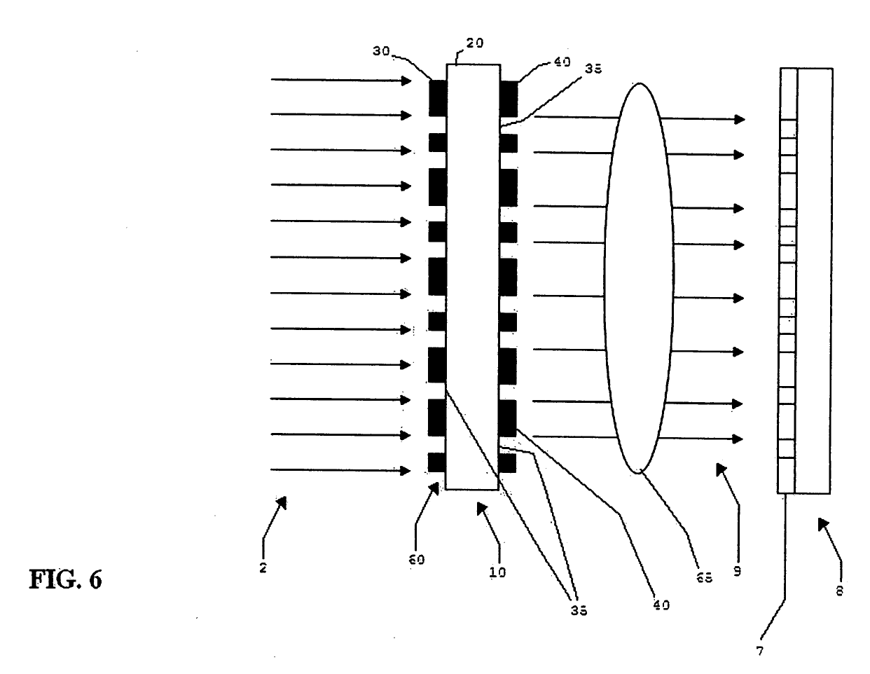

Lithographic photo masks according to the present invention are used as part of the optical projection lithographic system as shown in FIG. 6. In this system a light source (not shown) is disposed to direct light energy 2 to a first side 60 of a lithographic mask 10. The light source is any light source known to those of average skill in the art, and is preferably selected from the group consisting of a visible light source, an ultra-violet light source, an EUV light source and an x-ray light source. In a most preferred embodiment of the invention the light source is an ultra violet light source. The lithographic mask 10 comprises primary mask patterns 30 and secondary mask patterns 40 disposed on at least one photo mask substrate 20 whereby light 2 passing through unmasked regions 35 of the substrate 20 is collimated. A silicon wafer 8 with a photosensitive resist thin film 7 deposited thereon is disposed whereby the photosensitive resist thin film 7 is exposed by the collimated light 9. In a preferred embodiment at least one lens 65 is disposed to reduce and focus the collimated light 9 onto the photosensitive resist thin film 7.

The lithographic mask of the optical projection lithographic system is any light collimating photo mask, or light collimating system of photo masks as described above. The photo mask is either one double metal light collimating photo mask as shown in (FIG. 1) or a series of stacked photo masks as shown in FIG. 2, FIG. 3-A, FIG. 3-B, FIG. 4-A, FIG. 4-B, and FIG. 4-C.

To manufacture a double metal photo mask, a mask blank comprised of a transparent layer such as quartz is coated with opaque chromium metal thin films on both sides. A mask pattern is etched onto one metal side using standard mask fabrication technology such as laser beam or electron beam computer controlled direct writing. The second metal side is then processed to transfer the identical mask pattern such that it is aligned to the first mask pattern to provide collimation of illuminating actinic radiation.

To manufacture a light collimating stack of single sided masks, a standard single metal mask is processed using conventional techniques to etch the lithographic pattern into the chromium. Another single metal mask is processed with the same lithographic pattern. The two masks are then aligned one top of the other using alignment marks, or other techniques known to those of average skill in the art. The masks are then bonded together to form a light collimating mask.

The above description and drawings are only illustrative of preferred embodiments which achieve the objects features and advantages of the present invention, and it is not intended that the present invention be limited thereto. Any modification of the present invention which comes within the spirit and scope of the following claims is considered part of the invention.

What is claimed is:

1. A mask comprising:
at least one substantially transparent substrate having a first side and a second side,
wherein the first side and the second side are separated by thickness of the substrate;
wherein a primary mask pattern comprises an opaque layer formed on the substrate; and
wherein a secondary mask pattern comprises an opaque layer formed on the substrate; and
wherein the primary and secondary mask patterns act in unison to collimate light passing through unmasked regions of the substrate.

2. The mask according to claim 1, wherein the first side of the substrate comprises the primary mask pattern, and the second side of the substrate comprises the secondary mask pattern.

3. The mask according to claim 1, wherein the mask comprises a plurality of substrates; and
wherein the first side of at least one substrate comprises the primary mask pattern; and
wherein the first side of at least one substrate comprises the secondary mask pattern; and
wherein each substrate is aligned with respect to each other substrate, whereby light
passing through unmasked areas of the substrates is collimated.

4. The mask according to claim 1, wherein the substrate is selected from the group comprising quartz, LE-30, White Crown, borosilicate glass, and Soda Lime glass.

5. The mask according to claim 4, wherein the substrate is quartz.

6. The mask according to claim 1, wherein the opaque layer of the primary pattern is selected from the group comprising chromium, silver, chromium oxide, molybdenum, tungsten, titanium compounds, molybdenum silicon oxynitride, chrome oxynitride, and chromium aluminum oxynitride.

7. The mask according to claim 6, wherein the opaque layer of the primary mask pattern is chromium or silver.

8. The mask according to claim 1, wherein the opaque layer of the secondary mask pattern is selected from the group comprising chromium, silver, chromium oxide, molybdenum, tungsten, titanium compounds, molybdenum silicon oxynitride, chrome oxynitride, and chromium aluminum oxynitride.

9. The mask according to claim 8, wherein the opaque layer of the secondary mask pattern is chromium or silver.

10. The mask according to claim 1, wherein the primary mask pattern and the secondary mask pattern cover substantially identical areas of the substrate.

11. The mask according to claim 1, wherein the mask is a lithographic mask.

12. The mask according to claim 1, wherein the mask is a diffraction grating.

13. The mask according to claim 1, wherein at least one of the mask patterns comprises at least one pattern etched into the opaque layer on the substrate.

14. The mask according to claim 1, wherein the primary and secondary mask patterns comprise patterns etched into the opaque layer on the substrate, and wherein the primary mask pattern covers substantially the same regions of the substrate as the secondary mask pattern.

15. The mask according to claim 1, wherein the secondary mask pattern masks regions of the substrate not masked by the primary mask pattern.

16. The mask according to claim 1, wherein the secondary mask pattern has a dimensional offset bias with respect to the primary mask pattern.

17. The mask according to claim 1, wherein the substrate comprises a first substrate layer, and a second substrate layer, wherein the first substrate layer comprises the first mask pattern, and the second substrate layer comprises the second mask pattern.

18. The mask according to claim 17, wherein the substrate layers further comprise alignment marks to align the substrate layers with respect to one another.

19. A mask comprising:
at least one substrate selected from the group comprising quartz, LE-30, White Crown, borosilicate glass, and Soda Lime glass, the substrate having a first side and a second side,
wherein the first side and the second side are separated by thickness of the substrate; and
wherein the first side of the substrate comprises a primary mask pattern, and the second side of the substrate comprises a secondary mask pattern, the primary and secondary mask patterns selected from the group comprising chromium, chromium oxide, molybdenum, tungsten, titanium compounds, molybdenum silicon oxynitride, chrome oxynitride, and chromium aluminum oxynitride; and
wherein the primary mask pattern and the secondary mask pattern cover substantially identical areas of the substrate, whereby the primary mask pattern and the secondary mask pattern are disposed to collimate light passing through areas of the substrate not covered by the primary mask pattern and the secondary mask pattern.

20. The mask according to claim 19, wherein the mask is a lithographic photo mask.

21. The lithographic photo mask according to claim 20, wherein the primary and secondary mask patterns are chromium or silver, and the substrate is quartz.
wherein the primary and secondary mask patterns act in unison to collimate light passing through unmasked regions of the substrate.

22. An optical projection lithographic system comprising:
at least one lithographic mask, each mask comprising a substantially transparent substrate having a first side and a second side, wherein the first side and the second side are separated by thickness of the substrate;
wherein a primary mask pattern comprises an opaque layer formed on the first side of the substrate;
wherein a secondary mask pattern comprises an opaque layer formed on the second side of the substrate; and
at least one light source, wherein the light source is disposed to direct light energy to the first side of the lithographic mask; and wherein the primary and secondary mask patterns are disposed to collimate light passing through unmasked regions of the substrate.

23. The optical projection lithographic system according to claim 22, further comprising a focusing means to focus collimated light patterns on a wafer, wherein the focusing means is disposed between the mask and the wafer, whereby a reduced image of the mask is projected onto the wafer.

24. The optical projection lithographic system according to claim 22, wherein the light source is selected from the group consisting of a visible light source, an ultra-violet light source, an EUV light source and an x-ray light source.

25. The optical projection lithographic system according to claim 24, wherein the light source is an ultra-violet light source.

23-25. (canceled)

26. The optical projection lithographic system according to claim 23, wherein a plurality of substantially identical lithographic masks are disposed between the light source and the focusing means, wherein the mask patterns on each mask are substantially in alignment with the mask patterns on the other masks.

27. The optical projection lithographic system according to claim 22, wherein the substrate of the lithographic mask is selected from the group comprising quartz, LE-30, White Crown, borosilicate glass, and Soda Lime glass.

28. The optical projection lithographic system according to claim 27, wherein the substrate of the lithographic mask is a quartz substrate.

29. The optical projection lithographic system according to claim 22, wherein the opaque layer of the primary mask pattern is selected from the group comprising chromium, silver, chromium oxide, molybdenum, tungsten, titanium compounds, molybdenum silicon oxynitride, chrome oxynitride, and chromium aluminum oxynitride.

30. The optical projection lithographic system according to claim 29, wherein the opaque layer of the primary mask pattern is chromium or silver.

31. The optical projection lithographic system according to claim 22, wherein the opaque layer of the secondary mask pattern is selected from the group comprising chromium, silver, chromium oxide, molybdenum, tungsten, titanium compounds, molybdenum silicon oxynitride, chrome oxynitride, and chromium aluminum oxynitride.

32. The optical projection lithographic system according to claim 31, wherein the opaque layer of the secondary mask pattern is chromium or silver.

33. The optical projection lithographic system according to claim 22, wherein the primary and secondary mask patterns comprise substantially identical patterns etched into the opaque layer on the substrate.

34. The optical projection lithographic system according to claim 22, wherein the secondary mask pattern masks regions of the substrate not masked by the primary mask pattern.

35. The optical projection lithographic system according to claim 22, wherein the secondary mask pattern has a dimensional offset bias with respect to the primary mask pattern.

36. A method of manufacturing integrated circuit chips comprising the steps of:
1) providing an optical projection lithographic apparatus, the optical projection lithographic apparatus comprising:
at least one lithographic mask, each mask comprising a substantially transparent substrate having a first side and a second side, wherein the first side and the second side are separated by thickness of the substrate;
wherein a primary mask pattern comprises an opaque layer formed on the first side of the substrate;
wherein a secondary mask pattern comprises an opaque layer formed on the second side of the substrate; and
at least one light source, wherein the light source is disposed to direct light energy to the first side of the lithographic mask; and wherein the primary and secondary mask patterns are disposed to collimate light passing through unmasked regions of the substrate; and
2) providing a wafer comprising a layer of photo-resist, placing the wafer in the optical projection lithographic apparatus whereby collimated light exposes a pattern of the photo-resist layer; and
3) transferring the pattern from the photo-resist layer to the underlying wafer.

37. An integrated circuit chip manufactured through the process comprising the steps of:
1) providing an optical projection lithographic apparatus, the optical projection lithographic apparatus comprising:
at least one lithographic mask, each mask comprising a substantially transparent substrate having a first side and a second side, wherein the first side and the second side are separated by thickness of the substrate;
wherein a primary mask pattern comprises an opaque layer formed on the first side of the substrate;
wherein a secondary mask pattern comprises an opaque layer formed on the second side of the substrate; and
at least one light source, wherein the light source is disposed to direct light energy to the first side of the lithographic mask; and
wherein the primary and secondary mask patterns are disposed to collimate light passing through unmasked regions of the substrate; and
2) providing a wafer comprising a layer of photo-resist, placing the wafer in the optical projection lithographic apparatus whereby collimated light exposes a pattern of the photo-resist layer; and
3) transferring the pattern from the photo-resist layer to the underlying wafer.

38. The optical projection lithographic system according to claim 23, wherein the focusing means comprises at least one lens.

39. The optical projection lithographic system according to claim 22, wherein the
primary mask pattern and the secondary mask pattern cover substantially identical areas of the substrate.

40. The optical projection lithographic system according to claim 22, wherein a plurality of substantially identical lithographic masks are disposed whereby the mask patterns on each mask are substantially in alignment with the mask patterns on the other masks.
